(19) United States
(12) Patent Application Publication
(10) Pub. No.: US 2025/0169235 A1
(43) Pub. Date: May 22, 2025

(54) SEMICONDUCTOR LIGHT-EMITTING ELEMENT AND DISPLAY DEVICE

(71) Applicant: LG ELECTRONICS INC., Seoul (KR)

(72) Inventors: Yangwoo BYUN, Seoul (KR); Joodo PARK, Seoul (KR); Chunghyun LIM, Seoul (KR)

(73) Assignee: LG ELECTRONICS INC., Seoul (KR)

(21) Appl. No.: 18/840,316

(22) PCT Filed: Mar. 4, 2022
(86) PCT No.: PCT/KR2022/003100

§ 371 Date: Aug. 21, 2024

(51) Int. Cl. H10H 20/819; H10H 20/831; H10H 29/03; H10H 29/49

(52) U.S. Cl. CPC H10H 20/819; H10H 20/831; H10H 29/49; H10H 29/03

(57) ABSTRACT

The semiconductor light-emitting element includes a light-emitting portion, a first electrode under the light-emitting portion, a second electrode on the light-emitting portion, a passivation layer surrounding the light-emitting portion, and a first structure surrounding the passivation layer. Since the width is increased by the first structure, the aspect ratio (AR) is reduced, the semiconductor light-emitting element moves without being tilted during self-assembly, so that the assembly defect of semiconductor light-emitting element can be prevented, the assembly rate can be improved, and the assembly speed can be increased.

### TECHNICAL FIELD

The embodiment relates to a semiconductor light-emitting element and a display device.

### BACKGROUND ART

A large-area display includes a liquid crystal display (LCD), an OLED display, and a micro-LED display.

A micro-LED display is a display that uses a micro-LED, which is a semiconductor light-emitting element with a diameter or cross-sectional area of 100 μm or less, as a display element.

Since a micro-LED display uses a micro-LED, which is a semiconductor light-emitting element, as a display element, it has excellent performance in many characteristics such as contrast ratio, response speed, color reproducibility, viewing angle, brightness, resolution, lifespan, luminous efficiency, or luminance.

In particular, a micro-LED display has the advantage of being able to freely adjust the size or resolution by separating and combining the screen in a modular manner, and the advantage of being able to implement a flexible display.

However, since a large micro-LED display requires millions or more micro-LEDs, there is a technical problem that makes it difficult to quickly and accurately transfer micro-LEDs to the display panel.

Recently developed transfer technologies include the pick and place process, the laser lift-off method, or the self-assembly method.

Among these, the self-assembly method is a method in which semiconductor light-emitting elements find their assembly positions within a fluid, which is advantageous for implementing a large-screen display device.

However, research on the technology for manufacturing a display through self-assembly of micro-LEDs is still insufficient.

In particular, in the case of rapidly transferring millions or more semiconductor light-emitting elements to a large display in the conventional art, the transfer speed can be improved, but the transfer error rate can increase, which causes a technical problem in that the transfer yield decreases.

In the related art, a self-assembly method transfer process using dielectrophoresis (DEP) is being attempted, but there is a problem that the self-assembly rate is low due to the non-uniformity of a dielectrophoretic (DEP) force.

Meanwhile, in order to reduce the manufacturing cost and implement high resolution, the diameter (or size) of the semiconductor light-emitting element is becoming smaller and smaller. In contrast, since semiconductor materials having predetermined layers must be deposited, it is difficult to reduce the height (or thickness) of the semiconductor light-emitting element.

As shown in FIG. 1, the aspect ratio (hereinafter referred to as AR) of the semiconductor light-emitting element 1 is large. That is, the vertical width L12 is greater than the horizontal width L11. Here, the horizontal width L11 is the diameter of the semiconductor light-emitting element 1, and is becoming smaller and smaller in order to reduce the manufacturing cost and implement high resolution. In contrast, the vertical width L12 is the thickness of the semiconductor light-emitting element 1, and as described above, it is difficult to reduce. Therefore, in order to reduce the manufacturing cost and implement high resolution, as the width L11 of the semiconductor light-emitting element 1 becomes smaller and smaller, the AR increases.

Unexplained drawing symbol 2 represents a light-emitting portion comprising a plurality of semiconductor layers, and unexplained drawing symbol 3 represents a passivation layer.

According to the non-public internal technology, as illustrated in FIG. 2, the semiconductor light-emitting elements 1 are moved along the moving direction of the magnet 8 and assembled into the assembly hole 6 of the substrate 5. The semiconductor light-emitting elements 1 are moved along the magnet 8 in a fluid (not illustrated).

However, when the AR of the semiconductor light-emitting elements 1 is large, the semiconductor light-emitting elements 1 moving along the magnet 8 do not maintain their normal positions and are moved while tilted. That is, the major axis of the semiconductor light-emitting element 1 does not coincide with the vertical axis of the substrate 5 and is moved while tilted at a predetermined angle.

If the semiconductor light-emitting element 1 is moved while tilted without maintaining its normal position, as shown in FIG. 3, it tilts with respect to the assembly hole 6 of the substrate 5, and an assembly defect occurs in which it cannot be inserted into the assembly hole 6. In other words, since the semiconductor light-emitting element 1 does not move to the normal position of the substrate 6, an assembly defect occurs, and the assembly rate decreases. In FIG. 3, the unexplained symbol 7 represents a partition wall.

Meanwhile, according to the non-public internal technology, the semiconductor light-emitting element 1 is provided with a magnetic layer so as to be magnetized by the magnet 8. As the AR of the semiconductor light-emitting element 1 increases, the size of the magnetic layer decreases. Accordingly, even if magnet 8 is moved, there is a problem that the assembly rate is significantly reduced because the magnetization by magnet 8 is small and the semiconductor light-emitting elements 1 does not move along magnet 8.

### DISCLOSURE

### Technical Problem

An object of the embodiment is to solve the foregoing and other problems.

Another object of the embodiment is to provide a semiconductor light-emitting element and a display device having a new structure.

In addition, another object of the embodiment is to provide a semiconductor light-emitting element and a display device capable of preventing assembly failure by reducing AR.

In addition, another object of the embodiment is to provide a semiconductor light-emitting element and a display device capable of improving an assembly rate by reducing AR.

In addition, another object of the embodiment is to provide a semiconductor light-emitting element and a display device capable of increasing an assembly speed by increasing a size of a magnetic layer.

The technical problems of the embodiments are not limited to those described in this item and include those that can be understood through the description of the invention.

### Technical Solution

In order to achieve the above or other objects, according to one aspect of the embodiment, a semiconductor light-emitting element, comprises: a light-emitting portion; a first electrode under the light-emitting portion; a second electrode on the light-emitting portion; a passivation layer configured to surround the light-emitting portion; and a first structure configured to surround the passivation layer.

The first electrode may be disposed under the light-emitting portion, the passivation layer, and the first structure. The diameter of the first electrode may be at least 1.5 to 3 times the diameter D2 of the second electrode.

The first electrode may comprise a first region vertically overlapping the light-emitting portion; a second region vertically overlapping the passivation layer; and a third region vertically overlapping the first structure. The first region may have a circular or oval shape, and the second region and the third region may have ring shapes.

A second structure may be included on the first electrode. The second structure may be disposed between the first electrode and the first structure. The second structure may surround the passivation layer.

The first structure and the second structure may be laminated on the third region of the first electrode. The second structure may have a shape corresponding to the third region of the first electrode. The second structure may comprise a photosensitive member.

The first electrode may comprise at least a magnetic layer, and a diameter of the magnetic layer may be greater than a diameter of the light-emitting portion.

The first electrode may be disposed in some areas of a side portion of the first structure. The first electrode may comprise an extension electrode disposed in some areas of a side portion of the light-emitting portion.

The first structure may have a lower side and an upper side having different outer diameters. The first structure may comprise a transparent insulating member. The first structure may comprise reflective particles or scattering particles.

According to one aspect of the embodiment, a display device comprises a substrate comprising a plurality of sub-pixels; a plurality of first assembling wirings in the plurality of sub-pixels, respectively; a plurality of second assembling wirings in the plurality of sub-pixels, respectively; a partition wall having a plurality of assembly holes in the plurality of sub-pixels, respectively; a plurality of semiconductor light-emitting elements in the plurality of assembly holes, respectively; and a plurality of connection electrodes; wherein each of the plurality of semiconductor light-emitting elements comprises: a light-emitting portion; a first electrode under the light-emitting portion; a second electrode on the light-emitting portion; a passivation layer configured to surround the light-emitting portion; and a first structure configured to surround the passivation layer, and wherein each of the connection electrodes can connect the first electrode of each of the plurality of semiconductor light-emitting elements to at least one of the first assembling wiring or the second assembling wiring.

The connection electrode may be disposed between the first electrode and the structure.

### Advantageous Effects

As shown in FIGS. 11A and 11B and FIGS. 20 to 25, the embodiment can expand the horizontal width and reduce the aspect ratio (AR) by disposing the structure 158 around the passivation layer 157 of the semiconductor light-emitting element 150, 150A, 150B, 150C, 150D, 150E and 150F. Accordingly, as shown in FIG. 12, when the semiconductor light-emitting element 150 of the embodiment is moved by the magnet 500 for self-assembly in a fluid, the semiconductor light-emitting element 150 does not tilt and moves to a normal position that matches the vertical axis of the substrate 310, so that it is correctly assembled in the assembly hole 340H of the substrate 310, preventing assembly failure and improving the assembly rate.

In the embodiment, the first electrode 154 can be disposed under the light-emitting portion 151, 152, and 153 as well as the passivation layer 157 and the structure 158, so that the area of the first electrode 154 can be expanded. In this case, the area of the magnetic layer included in the first electrode 154 can be also expanded and the magnetization degree can be increased, so that the semiconductor light-emitting element 150 can be moved more quickly and rapidly by the magnet 500, as shown in FIG. 12, thereby improving the assembly speed.

As illustrated in FIGS. 23 to 25, a second structure 159 may be disposed between the first structure 158 and the first electrode 154 of the semiconductor light-emitting element 150D, 150E, and 150F. The second structure 159 may be easily removed by an exposure process. Accordingly, after the second structure 159 is removed during self-assembly, as illustrated in FIGS. 26 and 27, a connection electrode 330 may be formed in the space from which the second structure 159 was removed and connected to the side surfaces of the light-emitting portion 151, 152, and 153, thereby facilitating electrical connection to the side surfaces of the semiconductor light-emitting element 150D, 150E, and 150F.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 is a cross-sectional view illustrating a semiconductor light-emitting element having a large aspect ratio.

FIG. 2 illustrates a semiconductor light-emitting element having a large aspect ratio being assembled on a substrate.

FIG. 3 illustrates an assembly defect due to a semiconductor light-emitting element with a large aspect ratio.

FIG. 4 illustrates a living room of a house in which a display device according to an embodiment is disposed.

FIG. 5 is a block diagram schematically illustrating a display device according to an embodiment.

FIG. 6 is a circuit diagram illustrating an example of a pixel of FIG. 5.

FIG. 7 is an enlarged view of a first panel area in the display device of FIG. 4.

FIG. 8 is an enlarged view of an area A2 of FIG. 7.

FIG. 9 is a drawing illustrating an example in which a light-emitting element according to an embodiment is assembled to a substrate by a self-assembly method.

FIG. 10 is a cross-sectional view illustrating a display device according to a first embodiment.

FIG. 11A is a cross-sectional view illustrating a semiconductor light-emitting element according to the first embodiment.

FIG. 11B is a plan view illustrating a first electrode of a semiconductor light-emitting element.

FIG. 12 illustrates a view of semiconductor light-emitting elements according to the first embodiment being assembled on a substrate.

FIGS. 13 to 19 are flowcharts explaining a manufacturing method of a display device according to the first embodiment.

FIG. 20 is a cross-sectional view illustrating a semiconductor light-emitting element according to a second embodiment.

FIG. 21 is a cross-sectional view illustrating a semiconductor light-emitting element according to a third embodiment.

FIG. 22 is a cross-sectional view illustrating a semiconductor light-emitting element according to a fourth embodiment.

FIG. 23 is a cross-sectional view illustrating a semiconductor light-emitting element according to a fifth embodiment.

FIG. 24 is a cross-sectional view illustrating a semiconductor light-emitting element according to a sixth embodiment.

FIG. 25 is a cross-sectional view illustrating a semiconductor light-emitting element according to a seventh embodiment.

FIG. 26 is a cross-sectional view illustrating a display device according to a second embodiment.

FIG. 27 is a cross-sectional view illustrating a display device according to a third embodiment.

The sizes, shapes, dimensions, etc. of elements shown in the drawings can differ from actual ones. In addition, even if the same elements are shown in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

The display device described in this specification may comprise a TV, a signage, a mobile phone, a smart phone, a head-up display (HUD) for a car, a backlight unit for a laptop computer, a display for VR or AR, etc. However, the configuration according to the embodiment described in this specification may also be applied to a device capable of displaying, even if it is a new product type developed in the future.

The following describes a light-emitting element according to an embodiment and a display device comprising the same.

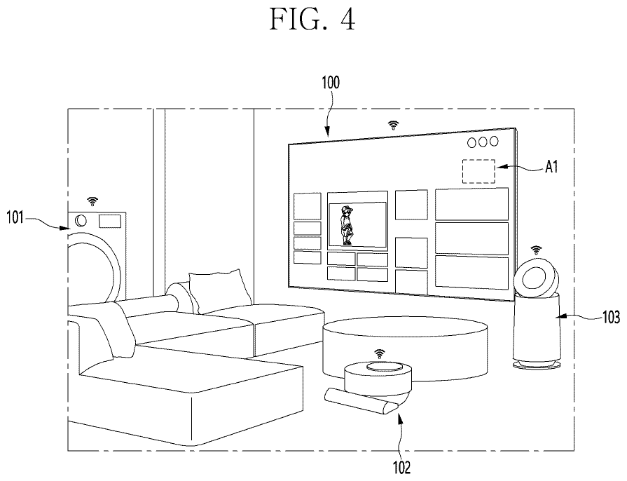

FIG. 4 illustrates a living room of a house in which a display device according to an embodiment is disposed.

Referring to FIG. 4, the display device 100 of the embodiment can display the status of various electronic products such as a washing machine 101, a robot vacuum cleaner 102, and an air purifier 103, and can communicate with each electronic product based on IOT and control each electronic product based on the user's setting data.

The display device 100 according to the embodiment may comprise a flexible display manufactured on a thin and flexible substrate. The flexible display may be bent or rolled like paper while maintaining the characteristics of a conventional flat panel display.

In the flexible display, visual information may be implemented by independently controlling the light emission of unit pixels disposed in a matrix form. A unit pixel means a minimum unit for implementing one color. The unit pixel of the flexible display may be implemented by a light-emitting element. In the embodiment, the light-emitting element may be a Micro-LED or a Nano-LED, but is not limited thereto.

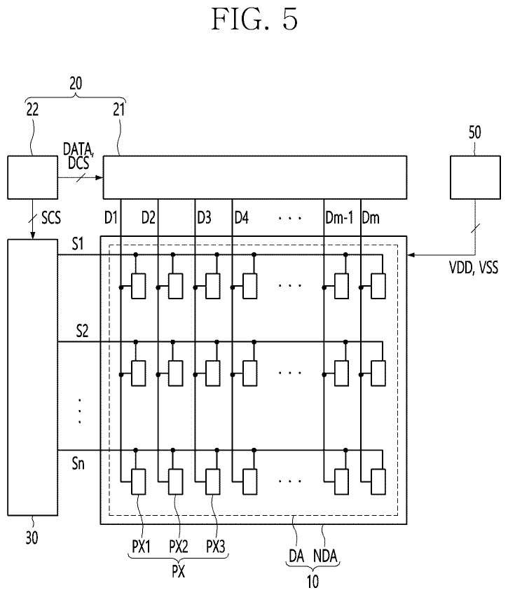

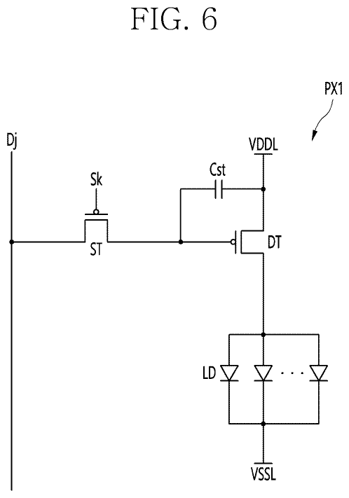

FIG. 5 is a block diagram schematically showing a display device according to the embodiment, and FIG. 6 is a circuit diagram showing an example of a pixel of FIG. 5.

Referring to FIG. 5 and FIG. 6, the display device according to the embodiment may comprise a display panel 10, a driving circuit 20, a scan driving unit 30, and a power supply circuit 50.

The display device 100 of the embodiment can drive a light-emitting element in an active matrix (AM) method or a passive matrix (PM) method.

The driving circuit 20 can comprise a data driving unit 21 and a timing control unit 22.

The display panel 10 can be formed in a rectangular shape, but is not limited thereto. That is, the display panel 10 can be formed in a circular or oval shape. At least one side of the display panel 10 can be formed to be bent at a predetermined curvature.

The display panel 10 can be divided into a display area DA and a non-display area NDA disposed around the display area DA. The display area DA is an area where pixels PX are formed to display an image. The display panel 10 may comprise data lines (D1 to Dm, where m is an integer greater than or equal to 2), scan lines (S1 to Sn, where n is an integer greater than or equal to 2) crossing the data lines D1 to Dm, a high-potential voltage line VDDL supplied with a high-potential voltage, a low-potential voltage line VSSL supplied with a low-potential voltage, and pixels PX connected to the data lines D1 to Dm and the scan lines S1 to Sn.

Each of the pixels PX may comprise a first sub-pixel PX1, a second sub-pixel PX2, and a third sub-pixel PX3. The first sub-pixel PX1 may emit a first color light of a first main wavelength, the second sub-pixel PX2 may emit a second color light of a second main wavelength, and the third sub-pixel PX3 may emit a third color light of a third main wavelength. The first color light may be red light, the second color light may be green light, and the third color light may be blue light, but the present invention is not limited thereto. In addition, although FIG. 5 exemplifies that each of the pixels PX comprises three sub-pixels, the present invention is not limited thereto. That is, each of the pixels PX may comprise four or more sub-pixels.

Each of the first sub-pixel PX1, the second sub-pixel PX2, and the third sub-pixel PX3 may be connected to at least one of the data lines D1 to Dm, at least one of the scan lines S1 to Sn, and a high-potential voltage line VDDL. The first sub-pixel PX1 may comprise light-emitting elements LD, a plurality of transistors for supplying current to the light-emitting elements LD, and at least one capacitor Cst, as shown in FIG. 6.

Although not shown in the drawing, each of the first sub-pixel PX1, the second sub-pixel PX2, and the third sub-pixel PX3 may comprise only one light-emitting element LD and at least one capacitor Cst.

Each of the light-emitting elements LD may be a semiconductor light-emitting diode comprising a first electrode, a plurality of conductivity-type semiconductor layers, and a second electrode. Here, the first electrode may be an anode electrode, and the second electrode may be a cathode electrode, but is not limited thereto.

The light-emitting element LD may be one of a lateral-tape light-emitting element, a flip-chip light-emitting element, and a vertical-type light-emitting element.

The plurality of transistors may comprise a driving transistor DT for supplying current to the light-emitting elements LD, and a scan transistor ST for supplying a data voltage to a gate electrode of the driving transistor DT, as shown in FIG. 6. The driving transistor DT may comprise a gate electrode connected to the source electrode of the scan transistor ST, a source electrode connected to a high-potential voltage line VDDL to which a high-potential voltage is applied, and a drain electrode connected to the first electrodes of the light-emitting elements LD. The scan transistor ST may comprise a gate electrode connected to a scan line (Sk, where k is an integer satisfying 1<k≤n), a source electrode connected to the gate electrode of the driving transistor DT, and a drain electrode connected to a data line (Dj, where j is an integer satisfying 1≤j≤m).

A capacitor Cst is formed between the gate electrode and the source electrode of the driving transistor DT. The storage capacitor Cst charges the difference between the gate voltage and the source voltage of the driving transistor DT.

The driving transistor DT and the scan transistor ST may be formed as thin film transistors. In addition, although FIG. 6 has been described with a focus on the driving transistor DT and the scan transistor ST being formed as P-type MOSFETs (Metal Oxide Semiconductor Field Effect Transistors), the present invention is not limited thereto. The driving transistor DT and the scan transistor ST may also be formed as N-type MOSFETs. In this case, the positions of the source electrodes and the drain electrodes of each of the driving transistor DT and the scan transistor STs may be changed.

In addition, FIG. 6 has been illustrated with an example in which each of the first sub-pixel PX1, the second sub-pixel PX2, and the third sub-pixel PX3 comprises 2T1C (2 Transistors-1 capacitor) having one driving transistor DT, one scan transistor ST, and one capacitor Cst, but the present invention is not limited thereto. Each of the first sub-pixel PX1, the second sub-pixel PX2, and the third sub-pixel PX3 may comprise a plurality of scan transistors STs and a plurality of capacitors Csts.

Since the second sub-pixel PX2 and the third sub-pixel PX3 may be expressed by substantially the same circuit diagram as the first sub-pixel PX1, a detailed description thereof will be omitted.

The driving circuit 20 outputs signals and voltages for driving the display panel 10. For this purpose, the driving circuit 20 may comprise a data driving unit 21 and a timing control unit 22.

The data driving unit 21 receives digital video data DATA and a source control signal DCS from the timing control unit 22. The data driving unit 21 converts the digital video data DATA into analog data voltages according to the source control signal DCS and supplies the converted data to data lines D1 to Dm of the display panel 10.

The timing control unit 22 receives digital video data DATA and timing signals from the host system. The timing signals may comprise a vertical synchronization signal, a horizontal synchronization signal, a data enable signal, and a dot clock. The host system may be an application processor of a smartphone or tablet PC, a monitor, a system on chip of a TV, etc.

The timing control unit 22 generates control signals for controlling the operation timing of the data driver 21 and the scan driver 30. The control signals may comprise a source control signal DCS for controlling the operation timing of the data driver 21 and a scan control signal SCS for controlling the operation timing of the scan driver 30.

The driving circuit 20 may be disposed in a non-display area NDA provided on one side of the display panel 10. The driving circuit 20 may be formed as an integrated circuit (IC) and mounted on the display panel 10 in a chip on glass (COG) manner, a chip on plastic (COP) manner, or an ultrasonic bonding manner, but the present invention is not limited thereto. For example, the driving circuit 20 may be mounted on a circuit board (not shown) other than the display panel 10.

The data driving unit 21 may be mounted on the display panel 10 in a chip on glass (COG) manner, a chip on plastic (COP) manner, or an ultrasonic bonding manner, and the timing control unit 22 may be mounted on the circuit board.

The scan driving unit 30 receives a scan control signal SCS from the timing control unit 22. The scan driving unit 30 generates scan signals according to the scan control signal SCS and supplies the scan signals to the scan lines S1 to Sn of the display panel 10. The scan driving unit 30 may comprise a plurality of transistors and may be formed in a non-display area NDA of the display panel 10. Alternatively, the scan driver 30 may be formed as an integrated circuit, in which case it may be mounted on a gate flexible film attached to the other side of the display panel 10.

The circuit board may be attached to pads provided on one edge of the display panel 10 using an anisotropic conductive film. As a result, lead lines of the circuit board may be electrically connected to the pads. The circuit board may be a flexible film, such as a flexible printed circuit board, a printed circuit board, or a chip on film. The circuit board may be bent to the lower part of the display panel 10. As a result, one side of the circuit board may be attached to one edge of the display panel 10, and the other side may be disposed on the lower part of the display panel 10 and connected to a system board on which a host system is mounted.

The power supply circuit 50 can generate voltages required for driving the display panel 10 from the main power applied from the system board and supply the voltages to the display panel 10. For example, the power supply circuit 50 can generate a high-potential voltage VDD and a low-potential voltage VSS for driving the light-emitting elements LD of the display panel 10 from the main power and supply them to the high-potential voltage line VDDL and the low-potential voltage line VSSL of the display panel 10. In addition, the power supply circuit 50 can generate and supply driving voltages for driving the driving circuit 20 and the scan driving unit 30 from the main power.

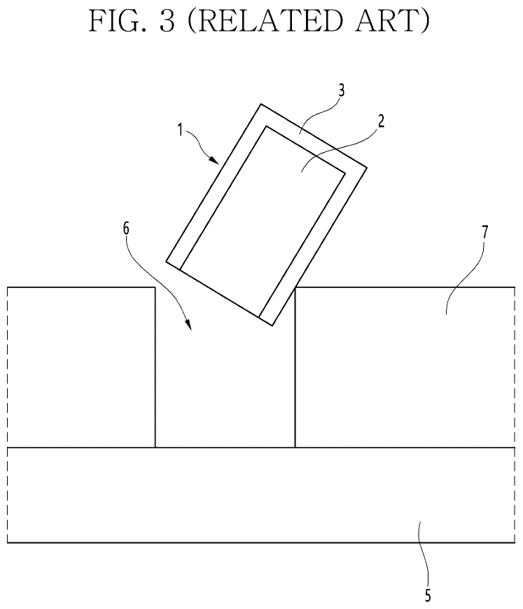

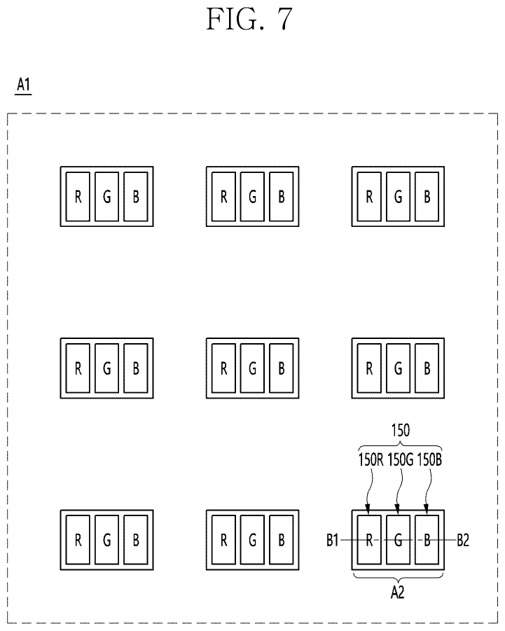

FIG. 7 is an enlarged view of the first panel area in the display device of FIG. 3.

Referring to FIG. 7, the display device 100 of the embodiment can be manufactured by mechanically and electrically connecting a plurality of panel areas such as the first panel area A1 by tiling.

The first panel area A1 may comprise a plurality of semiconductor light-emitting elements 150 disposed for each unit pixel (PX of FIG. 5).

For example, the unit pixel PX may comprise a first sub-pixel PX1, a second sub-pixel PX2, and a third sub-pixel PX3. For example, a plurality of red semiconductor light-emitting elements 150R may be disposed in the first sub-pixel PX1, a plurality of green semiconductor light-emitting elements 150G may be disposed in the second sub-pixel PX2, and a plurality of blue semiconductor light-emitting elements 150B may be disposed in the third sub-pixel PX3. The unit pixel PX may further comprise a fourth sub-pixel in which no semiconductor light-emitting elements are disposed, but is not limited thereto.

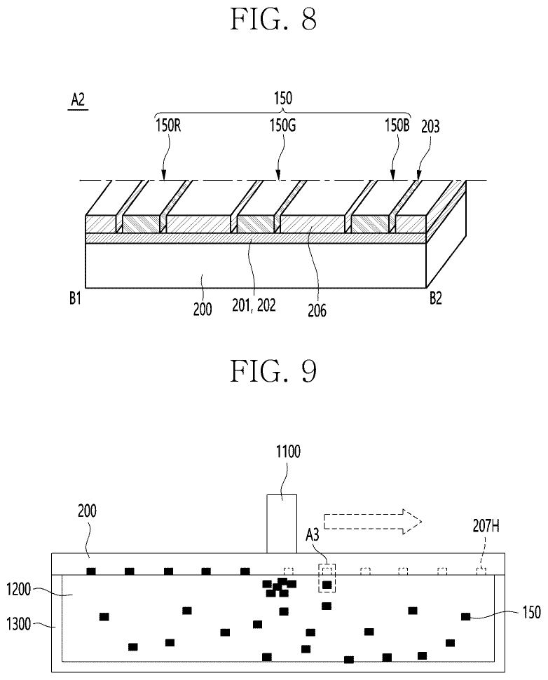

FIG. 8 is an enlarged view of the A2 area of FIG. 7.

Referring to FIG. 8, the display device 100 of the embodiment may comprise a substrate 200, assembling wirings 201 and 202, an insulating layer 206, and a plurality of semiconductor light-emitting elements 150. More components may be included.

The assembling wiring may comprise a first assembling wiring 201 and a second assembling wiring 202 that are spaced apart from each other. The first assembling wiring 201 and the second assembling wiring 202 may be provided to generate a dielectrophoretic force (DEP force) to assemble the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise, but is not limited thereto, a red semiconductor light-emitting element 150, a green semiconductor light-emitting element 150G, and a blue semiconductor light-emitting element 150B to form a unit pixel (sub-pixel), and may also comprise a red phosphor and a green phosphor to implement red and green, respectively.

The substrate 200 may be a support member that supports components disposed on the substrate 200, or a protective member that protects the components.

The substrate 200 may be a rigid substrate or a flexible substrate. The substrate 200 may be formed of sapphire, glass, silicon, or polyimide. In addition, the substrate 200 may comprise a flexible material such as polyethylene naphthalate (PEN), Polyethylene Terephthalate (PET). In addition, the substrate 200 may be a transparent material, but is not limited thereto. The substrate 200 can function as a support substrate in the display panel, and can also function as an assembling substrate when self-assembling the light-emitting element.

The substrate 200 can be a backplane equipped with circuits, such as transistors ST and DT, capacitors Cst, and signal wiring, within the sub-pixels PX1, PX2, and PX3 illustrated in FIGS. 5 and 6, but is not limited thereto.

The insulating layer 206 can comprise an organic material having insulation and flexibility, such as polyimide, PAC, PEN, PET, polymer, or an inorganic material, such as silicon oxide (SiO₂) or silicon nitride series (SiNₓ), and can be formed integrally with the substrate 200 to form a single substrate.

The insulating layer 206 can be a conductive adhesive layer having adhesiveness and conductivity, and the conductive adhesive layer can have flexibility to enable a flexible function of the display device. For example, the insulating layer 206 may be an anisotropic conductive film (ACF) or a conductive adhesive layer such as an anisotropic conductive medium, a solution containing conductive particles, etc. The conductive adhesive layer may be a layer that is electrically conductive in a direction vertical to the thickness, but electrically insulating in a direction horizontal to the thickness.

The insulating layer 206 may comprise an assembly hole 203 for inserting the semiconductor light-emitting element 150. Accordingly, during self-assembly, the semiconductor light-emitting element 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light-emitting element 150. For example, the red semiconductor light-emitting element, the green semiconductor light-emitting element, and the blue semiconductor light-emitting element each have different shapes, and may have an assembly hole 203 having a shape corresponding to each shape of these semiconductor light-emitting elements. For example, the assembly hole 203 may comprise a first assembly hole for assembling the red semiconductor light-emitting element, a second assembly hole for assembling the green semiconductor light-emitting element, and a third assembly hole for assembling the blue semiconductor light-emitting element. For example, the red semiconductor light-emitting element may have a circular shape, the green semiconductor light-emitting element may have a first oval shape having a first minor axis and a second major axis, and the blue semiconductor light-emitting element may have a second oval shape having a second minor axis and a second major axis, but is not limited thereto. The second major axis of the oval shape of the blue semiconductor light-emitting element may be greater than the second major axis of the oval shape of the green semiconductor light-emitting element, and the second minor axis of the oval shape of the blue semiconductor light-emitting element may be smaller than the first minor axis of the oval shape of the green semiconductor light-emitting element.

Meanwhile, the method of mounting the semiconductor light-emitting element 150 on the substrate 200 may comprise, for example, a self-assembly method (FIG. 9) and a transfer method.

FIG. 9 is a drawing showing an example in which a light-emitting element according to an embodiment is assembled on a substrate by a self-assembly method.

Based on FIG. 9, an example in which a semiconductor light-emitting element according to an embodiment is assembled on a display panel by a self-assembly method using an electromagnetic field will be described.

The assembling substrate 200 described below can also function as a panel substrate 200a in a display device after assembling the light-emitting element, but the embodiment is not limited thereto.

Referring to FIG. 9, the semiconductor light-emitting element 150 can be put into a chamber 1300 filled with a fluid 1200, and the semiconductor light-emitting element 150 can be moved to the assembling substrate 200 by a magnetic field generated from the assembly device 1100. At this time, the light-emitting element 150 adjacent to the assembly hole 207H of the assembling substrate 200 can be assembled into the assembly hole 207H by the DEP force caused by the electric field of the assembling wirings. The fluid 1200 can be water such as ultrapure water, but is not limited thereto. The chamber can be called a tank, a container, a vessel, etc.

After the semiconductor light-emitting element 150 is put into the chamber 1300, the assembling substrate 200 can be disposed on the chamber 1300. According to an embodiment, the assembling substrate 200 may be put into the chamber 1300.

After the assembling substrate 200 is disposed in the chamber, an assembly device 1100 that applies a magnetic field may move along the assembling substrate 200. The assembly device 1100 may be a permanent magnet or an electromagnet.

The assembly device 1100 may move in contact with the assembling substrate 200 to maximize the area affected by the magnetic field within the fluid 1200. According to an embodiment, the assembly device 1100 may comprise a plurality of magnetic bodies or may comprise magnetic bodies of a size corresponding to the assembling substrate 200. In this case, the movement distance of the assembly device 1100 may be limited within a predetermined range.

The semiconductor light-emitting element 150 in the chamber 1300 can be assembled in the assembly hole 207H by moving toward the assembly device 1100 and the assembling substrate 200 by the magnetic field generated by the assembly device 1100.

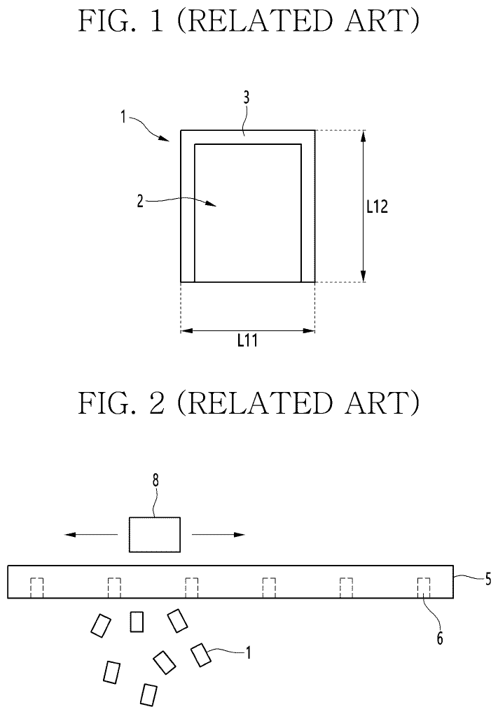

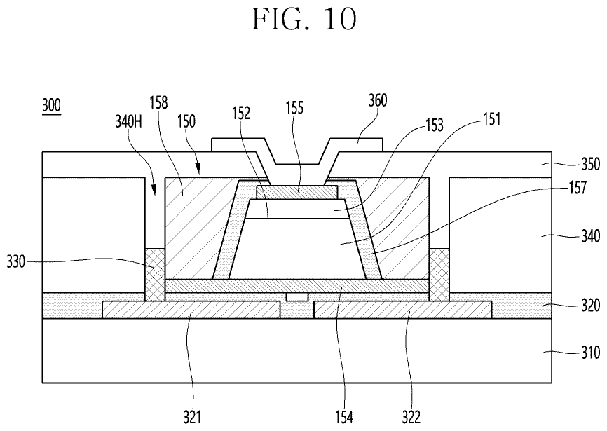

Hereinafter, various embodiments for solving the above-described problem will be described with reference to FIGS. 10 to 27. Any description omitted below can be easily understood from the descriptions described above with respect to FIGS. 1 to 9 and the corresponding drawings.

### First Embodiment

FIG. 10 is a cross-sectional view illustrating a display device according to a first embodiment. FIG. 10 illustrates one sub-pixel among a plurality of sub-pixels (PX1, PX2, PX3 of FIG. 5), and the display device 300 according to the first embodiment comprises a plurality of pixels, and each of the plurality of pixels may comprise a plurality of sub-pixels PX1, PX2, and PX3.

Referring to FIG. 10, the display device 300 according to the first embodiment may comprise a substrate 310, a first assembling wiring 321, a second assembling wiring 322, a partition wall 340, a semiconductor light-emitting element 150, and a connection electrode 330. The display device 300 according to the first embodiment may comprise more components than these.

The substrate 310 may comprise a plurality of sub-pixels PX1, PX2, and PX3. The plurality of sub-pixels may comprise a first sub-pixel PX1, a second sub-pixel PX2, and a third sub-pixel PX3. The first sub-pixel PX1, the second sub-pixel PX2, and the third sub-pixel PX3 may constitute a unit pixel capable of displaying a full color image. Therefore, by arranging a plurality of unit pixels on the substrate 310, a large-area image may be displayed.

For example, the first sub-pixel PX1 may emit a first color light, the second sub-pixel PX2 may emit a second color light, and the third sub-pixel may emit a third color light. The first color light may be red light, the second color light may be green light, and the third color light may be blue light, but are not limited thereto.

The substrate 310 may be a supporting member that supports components disposed on the substrate 310 or a protective member that protects the components. Since the substrate 310 has been described above, it is omitted.

The first and second assembling wirings 321 and 322 may be disposed on the substrate 310. That is, the plurality of sub-pixels PX1, PX2, and PX3 may each comprise the first assembling wiring 321 and the second assembling wiring 322. The first and second assembling wirings 321 and 322 can play a role in assembling the semiconductor light-emitting element 150 into the assembly hole 340H in a self-assembly manner. That is, when self-assembling, an electric field is generated between the first assembling wiring 321 and the second assembling wiring 322 by the voltage supplied to the first and second assembling wirings 321 and 322, and the semiconductor light-emitting element 150 moving by the assembly device (1100 of FIG. 10) can be assembled into the assembly hole 340H by the dielectrophoretic force formed by the electric field.

The first assembling wiring 321 and the second assembling wiring 322 can be disposed on the same layer. That is, the first assembling wiring 321 and the second assembling wiring 322 can be disposed between the substrate 310 and the first insulating layer 320. In this case, the first assembling wiring 321 and the second assembling wiring 322 may be disposed to be spaced apart from each other to prevent electrical shorts.

Although the first assembling wiring 321 and the second assembling wiring 322 are illustrated as being disposed on the same layer in the drawing, they may be disposed on different layers.

For example, the first assembling wiring 321 may be disposed under the first insulation layer 320, and the second assembling wiring 322 may be disposed on the first insulation layer 320. In this case, the upper surface of the second assembling wiring 322 may be exposed to the outside, i.e., to the assembly hole 340H. For example, the second assembling wiring 322 may form a part of the bottom portion of the assembly hole 340H. When the semiconductor light-emitting element 150 is assembled in the assembly hole 340H, the lower side of the semiconductor light-emitting element 150 may be in contact with the upper surface of the second assembling wiring 322 in the assembly hole 340H.

Referring again to FIG. 10, the first insulating layer 320 may be disposed on the first assembling wiring 321 and the second assembling wiring 322. For example, the first insulating layer 320 may prevent the first assembling wiring 321 and the second assembling wiring 322 from being electrically short-circuited by foreign substances. For example, the first insulating layer 320 may be made of a material having a permittivity, and may contribute to the formation of a dielectrophoretic force. For example, the first insulating layer 320 may be made of an inorganic material or an organic material. For example, the first insulating layer 320 may be made of a material having a permittivity related to a dielectrophoretic force.

The partition wall 340 may be disposed on the substrate 310 and may have an assembly hole 340H. Each of the plurality of sub-pixels PX1, PX2, and PX3 may comprise at least one or more assembly hole 340H. The partition wall 340 may be disposed on the first assembling wiring 321 and the second assembling wiring 322. For example, the assembly hole 340H may be provided on the first assembling wiring 321 and the second assembling wiring 322. The thickness of the partition wall 340 may be determined in consideration of the thickness of the semiconductor light-emitting element 150. For example, the thickness of the partition wall 340 may be smaller than the thickness of the semiconductor light-emitting element 150. Accordingly, the upper side of the semiconductor light-emitting element 150 may be positioned higher than the upper surface of the partition wall 340. That is, the upper side of the semiconductor light-emitting element 150 may protrude upward from the upper surface of the partition wall 340.

Each of the plurality of semiconductor light-emitting elements 150 may be assembled into the assembly hole 340H by the dielectrophoretic force formed between the first assembling wiring 321 and the second assembling wiring 322 in each of the plurality of sub-pixels PX1, PX2, and PX3. For example, one semiconductor light-emitting element 150 may be assembled into the assembly hole 340H.

The size of the assembly hole 340H may be determined by considering a tolerance margin for forming the assembly hole 340H and a margin for easily assembling the semiconductor light-emitting element 150 into the assembly hole 340H. For example, the size of the assembly hole 340H may be greater than the size of the semiconductor light-emitting element 150. For example, when the semiconductor light-emitting element 150 is assembled at the center of the assembly hole 340H, the distance between the outer side of the semiconductor light-emitting element 150 and the inner side of the assembly hole 340H may be 2 μm or less, but is not limited thereto.

For example, the assembly hole 340H may have a shape corresponding to the shape of the semiconductor light-emitting element 150. For example, if the semiconductor light-emitting element 150 is circular, the assembly hole 340H may also be circular. For example, if the semiconductor light-emitting element 150 is rectangular, the assembly hole 340H may also be rectangular.

As an example, the assembly holes 340H in each of the first sub-pixel PX1, the second sub-pixel PX2, and the third sub-pixel PX3 may have the same shape, that is, circular. In this case, the first semiconductor light-emitting element disposed in the first sub-pixel PX1, the second semiconductor light-emitting element disposed in the second sub-pixel PX2, and the third semiconductor light-emitting element disposed in the third sub-pixel PX3 may have a shape corresponding to the assembly hole 340H, that is, a circular shape.

In this way, when the assembly holes 340H of the first sub-pixel PX1, the second sub-pixel PX2, and the third sub-pixel PX3 have the same shape, the first semiconductor light-emitting element, the second semiconductor light-emitting element, and the third semiconductor light-emitting element may be sequentially assembled into the assembly holes 340H of the corresponding sub-pixels PX1, PX2, and PX3, respectively, but are not limited thereto. For example, the first semiconductor light-emitting element may be assembled into the assembly hole 340H of the first sub-pixel PX1 of the substrate 310, the second semiconductor light-emitting element may be assembled into the assembly hole 340H of the second sub-pixel PX2 of the substrate 310, and the third semiconductor light-emitting element may be assembled into the assembly hole 340H of the third sub-pixel PX3 of the substrate 310. In this case, the shapes of the first semiconductor light-emitting element, the second semiconductor light-emitting element, and the third semiconductor light-emitting element may be the same, but are not limited thereto. Each of the assembly holes 340H may have a shape corresponding to the shape of each of the first semiconductor light-emitting element, the second semiconductor light-emitting element, and the third semiconductor light-emitting element, but may have a size greater than each of the sizes of the first semiconductor light-emitting element, the second semiconductor light-emitting element, and the third semiconductor light-emitting element.

As another example, the assembly holes 340H in each of the first sub-pixel PX1, the second sub-pixel PX2, and the third sub-pixel PX3 may have different shapes. For example, the assembly hole 340H in the first sub-pixel PX1 may have a circular shape, the assembly hole 340H in the second sub-pixel PX2 may have a first oval shape having a first minor axis and a first major axis, and the assembly hole 340H in the third sub-pixel PX3 may have a second oval shape having a second minor axis smaller than the first minor axis and a second major axis greater than the first major axis. In this case, the first semiconductor light-emitting element may have a shape corresponding to the assembly hole 340H of the first sub-pixel PX1, that is, a circular shape, the second semiconductor light-emitting element may have a shape corresponding to the assembly hole 340H of the second sub-pixel PX2, that is, a first oval shape, and the third semiconductor light-emitting element may have a shape corresponding to the assembly hole 340H of the third sub-pixel PX3, that is, a second oval shape.

In this way, by the assembly holes 340H having different shapes and the first to third semiconductor light-emitting elements having shapes corresponding to each of the assembly holes 340H, the first to third semiconductor light-emitting elements may be assembled into the corresponding assembly holes 340H at the same time during self-assembly. That is, even if the first semiconductor light-emitting element, the second semiconductor light-emitting element, and the third semiconductor light-emitting element are mixed in the fluid 1200 for self-assembly, the semiconductor element corresponding to the assembly hole 340H of each of the first sub-pixel PX1, the second sub-pixel PX2, and the third sub-pixel PX3 on the substrate 310 can be assembled. That is, the first semiconductor light-emitting element having a shape corresponding to the shape of the assembly hole 340H of the first sub-pixel PX1 can be assembled. The second semiconductor light-emitting element having a shape corresponding to the shape of the assembly hole 340H of the second sub-pixel PX2 can be assembled. The third semiconductor light-emitting element having a shape corresponding to the shape of the assembly hole 340H of the third sub-pixel PX3 can be assembled. Accordingly, since the first semiconductor light-emitting element, the second semiconductor light-emitting element, and the third semiconductor light-emitting element, each having a different shape, are assembled in the assembly hole 340H corresponding to its shape, assembly failure can be prevented.

Meanwhile, the plurality of semiconductor light-emitting elements may comprise a first semiconductor light-emitting element emitting a first color light, a second semiconductor light-emitting element emitting a second color light, and a third semiconductor light-emitting element emitting a third color light. The first semiconductor light-emitting element, the second semiconductor light-emitting element, and the third semiconductor light-emitting element may be disposed in the first sub-pixel PX1, the second sub-pixel PX2, and the third sub-pixel PX3, respectively. For example, the first color light may comprise red light, the second color light may comprise green light, and the third color light may comprise blue light.

The semiconductor light-emitting element 150 of the embodiment may be a vertical-type semiconductor light-emitting element, but is not limited thereto. In this case, after the semiconductor light-emitting element 150 is assembled in the assembly hole 340H, the first electrode 154 of the semiconductor light-emitting element 150 can be electrically connected to the first assembling wiring 321 and/or the second assembling wiring 322. As will be described later, the second electrode 155 of the semiconductor light-emitting element 150 can be electrically connected to the electrode wiring 360.

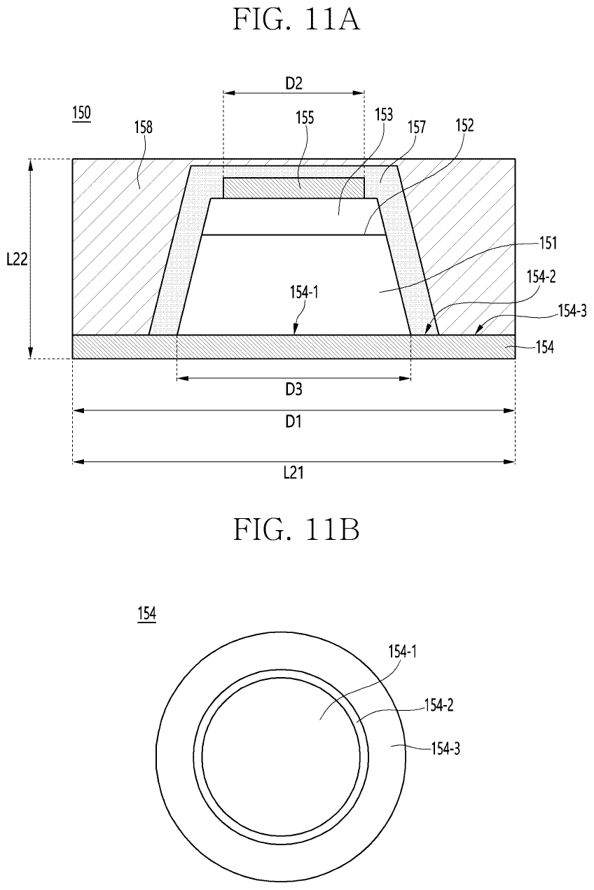

Referring to FIGS. 11A and 11B, a semiconductor light-emitting element according to the first embodiment will be described.

FIG. 11A is a cross-sectional view illustrating a semiconductor light-emitting element according to the first embodiment. FIG. 11B is a plan view illustrating a first electrode of the semiconductor light-emitting element.

Referring to FIG. 11A, the semiconductor light-emitting element 150 according to the first embodiment may comprise a first electrode 154, light-emitting portion 151, 152, and 153, a passivation layer 157, a structure 158, and a second electrode 155. The semiconductor light-emitting element 150 according to the first embodiment may comprise more components than these.

The light-emitting portion 151, 152, and 153 may be disposed on the first electrode 154. The passivation layer 157 may be disposed on the first electrode 154. The structure may be disposed on the first electrode 154. The second electrode 155 may be disposed on the light-emitting portion 151, 152, and 153.

The light-emitting portion 151, 152, and 153 may emit light of a predetermined color. The light-emitting portion 151, 152, and 153 comprise a first conductivity-type semiconductor layer 151, an active layer 152, and a second conductivity-type semiconductor layer 153, but may comprise more components than these. That is, each of the first conductivity-type semiconductor layer 151, the active layer 152, and the second conductivity-type semiconductor layer 153 may comprise a plurality of layers.

The first conductivity-type semiconductor layer 151, the active layer 152, and the second conductivity-type semiconductor layer 153 may be sequentially grown on a wafer (not shown) using a deposition device such as MOCVD. That is, the first conductivity-type semiconductor layer 151 may be grown, then the active layer 152 may be grown on the first conductivity-type semiconductor layer 151, and then the second conductivity-type semiconductor layer 153 may be grown on the active layer 152. Afterwards, the second conductivity-type semiconductor layer 153, the active layer 152, and the first conductivity-type semiconductor layer 151 may be etched in the vertical direction in this order using an etching process. Through this etching process, a plurality of light-emitting portions 151, 152, and 153 may be spaced apart from each other on the first substrate (1000 of FIG. 15a), and the first substrate 1000 may be removed, thereby separating the plurality of light-emitting portions 151, 152, and 153. Through this etching process, various shapes of light-emitting portion 151, 152, and 153 may be formed.

The first conductivity-type semiconductor layer 151, the active layer 152, and the second conductivity-type semiconductor layer 153 may be formed of a group III-V compound semiconductor material or a group II-VI compound semiconductor material. Each of the first conductivity-type semiconductor layer 151, the active layer 152, and the second conductivity-type semiconductor layer 153 may comprise a plurality of layers.

The first conductivity-type semiconductor layer 151 may comprise a first conductive dopant, and the second conductivity-type semiconductor layer 153 may comprise a second conductive dopant. For example, the first conductive dopant may be an n-type dopant such as silicon (Si), and the second conductive dopant may be a p-type dopant such as boron (B).

For example, the first conductivity-type semiconductor layer 151 may generate electrons, and the second conductivity-type semiconductor layer 153 may form holes. The active layer 152 may be called an emission layer because it generates light by recombination of electrons and holes.

For example, the first conductivity-type semiconductor layer 151 may generate electrons, and the second conductivity-type semiconductor layer 153 may form holes. The active layer 152 generates light by the recombination of electrons and holes and may be called a light-emitting layer.

When the semiconductor light-emitting element 150 according to the first embodiment is formed by mesa etching, the diameter of the semiconductor light-emitting element 150 may become increasingly larger from the upper side to the lower side.

The first electrode 154 may be disposed under the light-emitting portion 151, 152, and 153, and the second electrode 155 may be disposed on the light-emitting portion 151, 152, and 153. For example, the first electrode 154 may be disposed under the first conductivity-type semiconductor layer 151, and the second electrode 155 may be disposed on the second conductivity-type semiconductor layer 153. The first electrode 154 and the second electrode 155 may be called a lower electrode and an upper electrode, respectively.

When power is applied to the first electrode 154 and the second electrode 155, electrons may be generated in the first conductivity-type semiconductor layer 151 and injected into the active layer 152, and holes may be generated in the second conductivity-type semiconductor layer 153 and injected into the active layer 152. As the electrons and holes recombine in the active layer 152, a predetermined color light may be generated. The color light may comprise light having a wavelength band corresponding to a band gap determined according to the semiconductor material of the active layer 152.

The first electrode 154 may comprise a plurality of layers. For example, the first electrode 154 may further comprise a magnetic layer, a reflective layer, an adhesive layer, a barrier layer, etc. For example, the magnetic layer may be made of nickel (Ni), cobalt (Co), iron (Fe), etc. For example, the reflective layer may be made of aluminum (Al), silver (Ag), etc.

The second electrode 155 may be disposed on the light-emitting portion 151, 152, and 153. For example, the second electrode 155 may be disposed on the second conductivity-type semiconductor layer 153. The second electrode 155 may comprise a plurality of layers. For example, the second electrode 155 may comprise a transparent conductive layer, etc. The transparent conductive layer may be made of, for example, ITO, IZO, etc. A current spreading effect may be obtained in which the current supplied by the voltage from the electrode wiring 360 is evenly spread to the entire area of the second conductivity-type semiconductor layer 153 by the transparent conductive layer. That is, since the current is evenly spread across the entire area of the second conductive semiconductor layer 153 by the transparent conductive layer, and holes are generated across the entire area of the second conductive semiconductor layer 153, the amount of light generated by the recombination of holes and electrons in the active layer 152 can be increased by increasing the amount of hole generation, thereby increasing the light efficiency. The increase in light efficiency can lead to an improvement in brightness.

The passivation layer 157 can protect the light-emitting portion 151, 152, and 153. The passivation layer 157 can block leakage current flowing to the outer surfaces of the light-emitting portion 151, 152, and 153, thereby reducing power consumption, and can prevent an electrical short between the side surface of the first conductivity-type semiconductor layer 151 and the side surface of the second conductivity-type semiconductor layer 153 caused by foreign substances.

The passivation layer 157 may be an inorganic material, for example, SiNₓ or SiOₓ.

For example, the passivation layer 157 may surround the light-emitting portion 151, 152, and 153. For example, the passivation layer 157 may surround the second electrode 155. For example, the passivation layer 157 may be disposed along the perimeter of the side portion of the light-emitting portion 151, 152, and 153 and may be disposed on the second electrode 155.

The passivation layer 157 may prevent the semiconductor light-emitting element 150 from being flipped over during self-assembly, and may allow the lower side of the semiconductor light-emitting element 150, that is, the lower surface of the first conductivity-type semiconductor layer 151, to face the upper surface of the first insulating layer 320. That is, during self-assembly, the passivation layer 157 of the semiconductor light-emitting element 150 can be positioned to be away from the first assembling wiring 321 and the second assembling wiring 322. Since the passivation layer 157 is not disposed on the lower side of the semiconductor light-emitting element 150, the lower side of the semiconductor light-emitting element 150 can be positioned to be closer to the first assembling wiring 321 and the second assembling wiring 322. Therefore, during self-assembly, the lower side of the semiconductor light-emitting element 150 is positioned to face the first insulating layer 320, and the upper side of the semiconductor light-emitting element 150 is positioned to face the upper direction, thereby preventing mis-alignment in which the semiconductor light-emitting element 150 is assembled upside down.

The drawing illustrates that the upper sides of the light-emitting portion 151, 152, and 153 are covered by the passivation layer 157, but is not limited thereto. That is, the passivation layer 157 on the upper side of the light-emitting portion 151, 152, and 153 and a portion of each of the structures can be removed to form an opening in which the upper side of the light-emitting portion 151, 152, and 153, i.e., the second electrode 155, is exposed. After the semiconductor light-emitting element 150 having the light-emitting portion 151, 152, and 153 with the opening formed in this way is assembled on the substrate 310 using a self-assembly process, the electrode wiring 360 can be connected through the opening.

Meanwhile, the structure can surround the passivation layer 157. For example, the structure can be an organic material such as PAC (polyacrylate), but is not limited thereto. For example, the structure can be made of a resin material such as epoxy.

The structure can cover the entire area of the side portion of the passivation layer 157. The structure may cover the passivation layer 157 corresponding to the second electrode 155.

The AR may be reduced by the structure. That is, the width L21 may be increased by the structure.

According to the non-public internal technology, the width (L11 of FIG. 1) may correspond to the diameter of the light-emitting portion 151, 152, and 153.

However, in an embodiment, the width L21 of the semiconductor light-emitting element 150 may be greater than the diameter D3 of the light-emitting portion 151, 152, and 153 by the structure. That is, in the embodiment, the width L21 corresponds to the diameter D1 and may be determined (or calculated) by the diameter D3 of the light-emitting portion 151, 152, and 153, twice the width of the passivation layer 157, and twice the width of the structure.

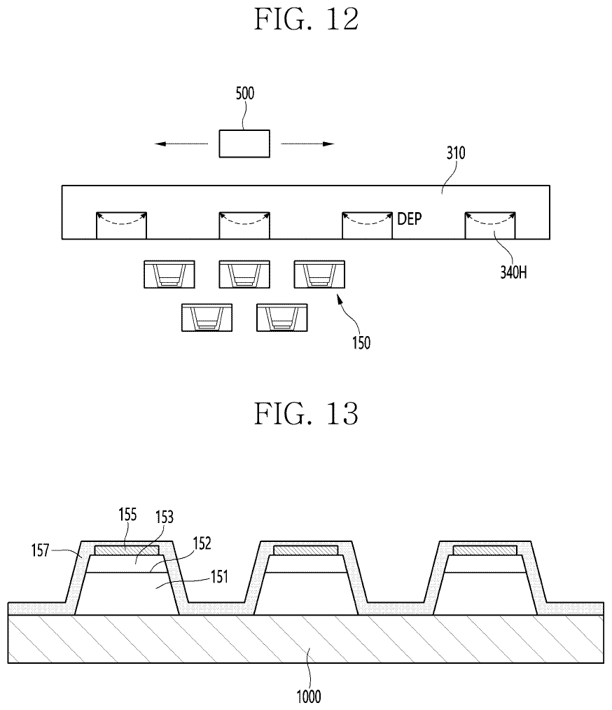

Assuming that the vertical width L22 is the same as the vertical width L12 in the non-public internal technology, as the horizontal width L21 of the semiconductor light-emitting element 150 of the embodiment increases, the AR (L22/L21) of the embodiment can be much smaller than the AR (L12/L11) in the non-public internal technology. Accordingly, as illustrated in FIG. 12, when the semiconductor light-emitting element 150 of the embodiment is moved by the magnet 500 for self-assembly in a fluid, the semiconductor light-emitting element 150 does not tilt and moves to a normal position that matches the vertical axis of the substrate 310, so that it is correctly assembled in the assembly hole 340H of the substrate 310, thereby preventing an assembly defect and improving the assembly rate. In other words, in the embodiment, the structure is disposed to surround the passivation layer 157, thereby reducing the AR, so that the semiconductor light-emitting element 150 having the structure moves to the correct position in the fluid during self-assembly and is correctly assembled into the assembly hole 340H on the substrate 310, thereby preventing assembly failure and improving the assembly rate.

Meanwhile, the first electrode 154 may comprise a first region 154-1, a second region 154-2, and a third region 154-3.

As illustrated in FIG. 11B, the center of the first region 154-1 may coincide with the centers of the light-emitting portion 151, 152, and 153. The first region 154-1 may have a circular or oval shape. The second region 154-2 may surround the first region 154-1, and the third region 154-3 may surround the second region 154-2. The second region 154-2 and the third region 154-3 may each have a ring shape. The second region 154-2 and the third region 154-3 may each have a closed-loop shape.

The first region 154-1 of the first electrode 154 may have a shape corresponding to the shape of the light-emitting portion 151, 152, and 153. The area of the first region 154-1 of the first electrode 154 may be the same as the area of the lower surface of the light-emitting portion 151, 152, and 153. The diameter of the first region 154-1 of the first electrode 154 may be the same as the diameter D3 of the lower surface of the light-emitting portion 151, 152, and 153. The first region 154-1 of the first electrode 154 may vertically overlap with the light-emitting portion 151, 152, and 153.

The second region 154-2 of the first electrode 154 may have a shape corresponding to the shape of the passivation layer 157. The second region 154-2 of the first electrode 154 may vertically overlap with the passivation layer 157.

The third region 154-3 of the first electrode 154 may have a shape corresponding to the shape of the structure. The third region 154-3 of the first electrode 154 may vertically overlap with the structure.

The diameter D1 of the first electrode 154 may be greater than the diameter D3 of the light-emitting portion 151, 152, and 153. The diameter D1 of the first electrode 154 may be greater than the diameter D3 of the lower surface of the light-emitting portion 151, 152, and 153. The diameter D1 of the first electrode 154 may be at least 1.5 to 3 times greater than the diameter D2 of the second electrode 155.

In the embodiment, the area of the first electrode 154 may be expanded by the structure, and since the first electrode 154 comprises at least a magnetic layer, the area of the magnetic layer may also be expanded. As the area of the magnetic layer is expanded, the magnetization may increase. Therefore, the magnetization of the semiconductor light-emitting element 150 having the first electrode 154 may be significantly increased by the magnet (500 of FIG. 12) during self-assembly, so that the semiconductor light-emitting element 150 can move along the magnet 500 more quickly and rapidly, so that the assembly speed can be significantly increased.

Meanwhile, the structure can comprise a transparent insulating member. Therefore, light generated from the semiconductor light-emitting element 150, transmitted through the passivation layer 157, and incident on the structure may be refracted in various directions by the structure and emitted forward, so that uniform light output can be possible and light efficiency can be improved.

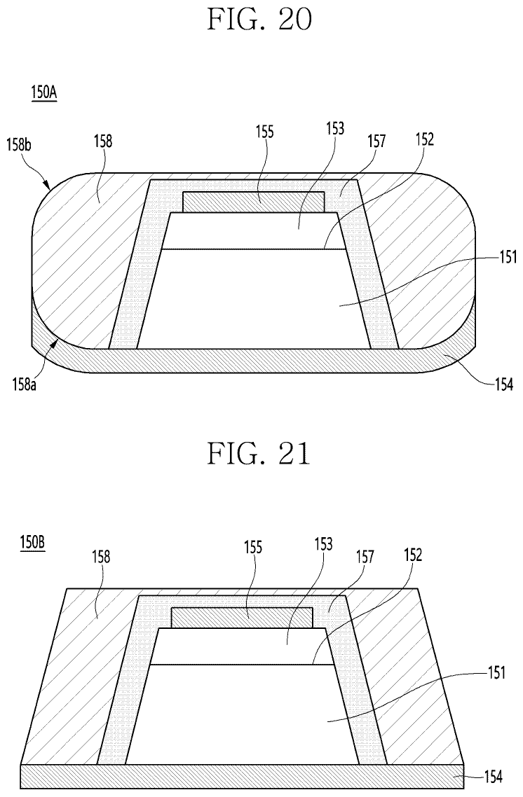

For the refractive index of light in various directions, the appearance of the structure can be variously modified. Various modified structures of the structure will be described later with reference to FIGS. 20 to 25.

Meanwhile, the structure can comprise reflective particles or scattering particles. Accordingly, since light incident on the structure is reflected or scattered in various directions by reflective particles or scattering particles and emitted forward, uniform light output can be possible and light efficiency can be improved.

Meanwhile, referring to FIG. 10 again, the connection electrode 330 can be disposed in the assembly hole 340H. For example, the connection electrode 330 can electrically connect the first conductivity-type semiconductor layer 151 of the semiconductor light-emitting element 150 and the first assembling wiring 321 and/or the second assembling wiring 322 in the assembly hole 340H. For example, one side of the connection electrode 330 can be electrically connected to a side portion of the first conductivity-type semiconductor layer 151 of the semiconductor light-emitting element 150, and the other side of the connection electrode 330 can be electrically connected to a portion of the upper surface of the first assembling wiring 321 and/or the second assembling wiring 322. For example, the connection electrode 330 may be electrically connected to the semiconductor light-emitting element 150 along the perimeter of the side portion of the first conductivity-type semiconductor layer 151 of the semiconductor light-emitting element 150. Accordingly, the contact area between the connection electrode 330 and the first conductivity-type semiconductor layer 151 is significantly increased, so that the current flows more quickly and smoothly from the first conductivity-type semiconductor layer 151 to the connection electrode 330, thereby improving the light efficiency.

For example, the connection electrode 330 may contact a portion of the upper surface of the first assembling wiring 321 and/or the second assembling wiring 322 through the first insulating layer 320. For example, the connection electrode 330 may contact a side portion of the first electrode 154 of the semiconductor light-emitting element 150. The thickness of the connection electrode 330 may be smaller than the thickness of the partition wall 340.

Meanwhile, the connection electrode 330 may comprise at least one or more layer. For example, the connection electrode 330 may comprise a metal having excellent electrical conductivity, high reflectivity, and high thermal conductivity. The connection electrode 330 may comprise aluminum (Al) or silver (Ag). Aluminum (Al) is easily oxidized. Accordingly, the connection electrode 330 may comprise molybdenum (Mo) to prevent oxidation of aluminum (Al).

The connection electrode 330 may comprise a first layer, a second layer, and a third layer. The first layer may be disposed under the second layer, and the third layer may be disposed on the second layer. For example, the second layer may comprise aluminum or silver. At least one of the first layer or the second layer may comprise molybdenum.

Meanwhile, the display device 300 according to the first embodiment may comprise a second insulating layer 350 and an electrode wiring 360.

The second insulating layer 350 may be disposed on the partition wall 340 to protect the semiconductor light-emitting element 150. The second insulating layer 350 may be disposed in the assembly hole 340H around the semiconductor light-emitting element 150 to firmly fix the semiconductor light-emitting element 150. In addition, the second insulating layer 350 may be disposed on the semiconductor light-emitting element 150 to protect the semiconductor light-emitting element 150 from external impact and prevent it from being contaminated by foreign substances.

The second insulating layer 350 may serve as a planarization layer that allows a layer formed in a subsequent process to be formed with a constant thickness. Accordingly, the upper surface of the second insulating layer 350 may have a flat surface. The second insulating layer 350 may be formed of an organic material or an inorganic material. Accordingly, the electrode wiring 360 may be easily formed without a short circuit on the upper surface of the second insulating layer 350 having a flat surface.

The electrode wiring 360 may be disposed in each of the first sub-pixel PX1, the second sub-pixel PX2, and the third sub-pixel PX3. One side of the electrode wiring 360 may be connected to a signal line (not shown), and the other side of the electrode wiring 360 may be connected to the second electrode 155 of the semiconductor light-emitting element 150.

For example, the electrode wiring 360 may be made of a transparent conductive material that allows light to pass through. For example, the electrode wiring 360 may comprise ITO, IZO, etc., but is not limited thereto.

The semiconductor light-emitting element 150 may emit light by power supplied by the first assembling wiring 321 and/or the second assembling wiring 322 connected to the connection electrode 330 and the electrode wiring 360. The first assembling wiring 321 and/or the second assembling wiring 322 connected to the connection electrode 330 may be used as the first electrode wiring, and the electrode wiring 360 may be the second electrode wiring.

FIGS. 13 to 19 are flowcharts explaining a method of manufacturing a display device according to the first embodiment.

As illustrated in FIG. 13, the light-emitting portion 151, 152, and 153 may be formed on the first substrate 1000.

The first substrate 1000 may be a growth substrate for growing the first conductivity-type semiconductor layer 151, the active layer 152, and the second conductivity-type semiconductor layer 153 of the light-emitting portion 151, 152, and 153.

Specifically, the first conductivity-type semiconductor layer 151, the active layer 152, and the second conductivity-type semiconductor layer 153 may be sequentially deposited on the first substrate 1000. The first conductivity-type semiconductor layer 151, the active layer 152, and the second conductivity-type semiconductor layer 153 may be deposited using, for example, an MOCVD equipment. For example, the first substrate 1000 may be a semiconductor growth substrate such as sapphire or GaAs. Each of the first conductivity-type semiconductor layer 151, the active layer 152, and the second conductivity-type semiconductor layer 153 may comprise at least one or more layer.

Although not shown, a third semiconductor layer may be deposited before depositing the first conductivity-type semiconductor layer 151. The third semiconductor layer is an undoped semiconductor layer that does not comprise a dopant, and may serve as a seed for easily growing the first conductivity-type semiconductor layer 151, the active layer 152, and the second conductivity-type semiconductor layer 153.

An etching process may be performed, so that the second conductivity-type semiconductor layer 153, the active layer 152, and the first conductivity-type semiconductor layer 151 may be removed, so that a plurality of light-emitting portions 151, 152, and 153 spaced apart from each other may be formed. For example, mesa etching may be performed, so that the diameter of the light-emitting portion 151, 152, and 153 may become smaller from the upper side to the lower side.

A second electrode 155 may be formed on the second conductivity-type semiconductor layer 153 of the light-emitting portion 151, 152, and 153.

As an example, the second electrode 155 may be formed on the second conductivity-type semiconductor layer 153 before the light-emitting portion 151, 152, and 153 are formed. Thereafter, after the second electrode 155 is patterned, an etching process may be performed using the second electrode 155 as a mask, thereby forming the light-emitting portion 151, 152, and 153.

As another example, after the light-emitting portion 151, 152, and 153 are formed through the etching process, the second electrode 155 may be formed on the second conductivity-type semiconductor layer 153.

The second electrode 155 may be formed of a conductive oxide material that transmits light, i.e., visible light. As described above, ITO, IZO, etc. may be used as the conductive oxide material.

A passivation layer 157 may be formed on the first substrate 1000. That is, the passivation layer 157 may be formed on the entire area of the first substrate 1000. The passivation layer 157 may be an inorganic material, such as SiNₓ or SiOₓ.

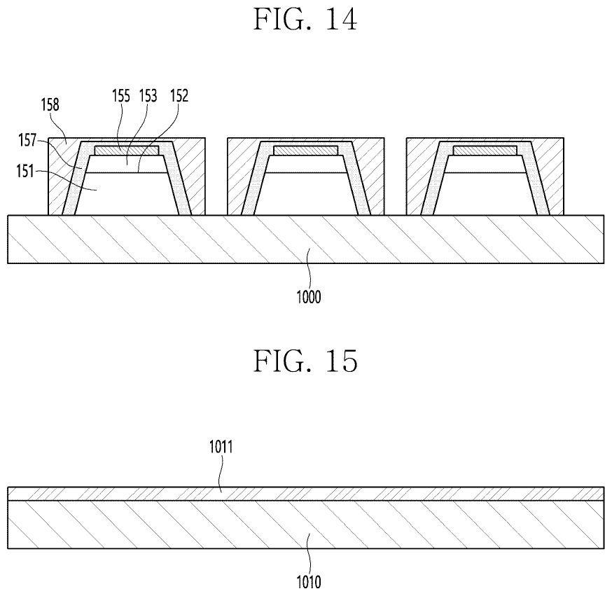

As illustrated in FIG. 14, an organic film may be formed on the passivation layer 157, and the organic film may be patterned to form a structure. The structure may be formed around the light-emitting portion 151, 152, and 153. The organic film may be formed of a organic material such as polyacrylate (PAC), but is not limited thereto. Instead of the organic film, a photosensitive film may be used. The photosensitive film may be patterned using an exposure process, so that a photosensitive pattern may be formed around the light-emitting portion 151, 152, and 153.

An etching process may be performed using the structure as a mask, so that the remaining passivation layers 157 except for the passivation layers 157 corresponding to the structure are removed, so that the passivation layers 157 may be formed around the light-emitting portion 151, 152, and 153. For example, the passivation layers 157 may be formed on the upper side of the light-emitting portion 151, 152, and 153, that is, on the second electrode 155. For example, the passivation layers 157 may be formed along the perimeter of the light-emitting portion 151, 152, and 153.

The passivation layer 157 can prevent an electrical short between the first conductivity-type semiconductor layer 151 and the second conductivity-type semiconductor layer 153 due to a foreign substance. The passivation layer 157 can prevent leakage current flowing through the side portion of each of the first conductivity-type semiconductor layer 151 and the second conductivity-type semiconductor layer 153. The passivation layer 157 can ensure that the semiconductor light-emitting element 150 is correctly assembled without being flipped over during self-assembly.

As illustrated in FIG. 15, a second substrate 1010 comprising a sacrificial layer 1011 can be provided. The second substrate 1010 can be glass, but is not limited thereto. The sacrificial layer 1011 is made of a metal such as aluminum (Al), and any material that can be removed by an etchant is acceptable.

As shown in FIG. 16, the second substrate 1010 and the first substrate 1000 can be bonded to each other. For this purpose, an adhesive layer (not shown) can be provided on the sacrificial layer 1011. Therefore, the first substrate 1000 and the second substrate 1010 can be bonded to each other via the adhesive layer. That is, the structure of the first substrate 1000 and the sacrificial layer 1011 of the second substrate 1010 can be bonded via the adhesive layer.

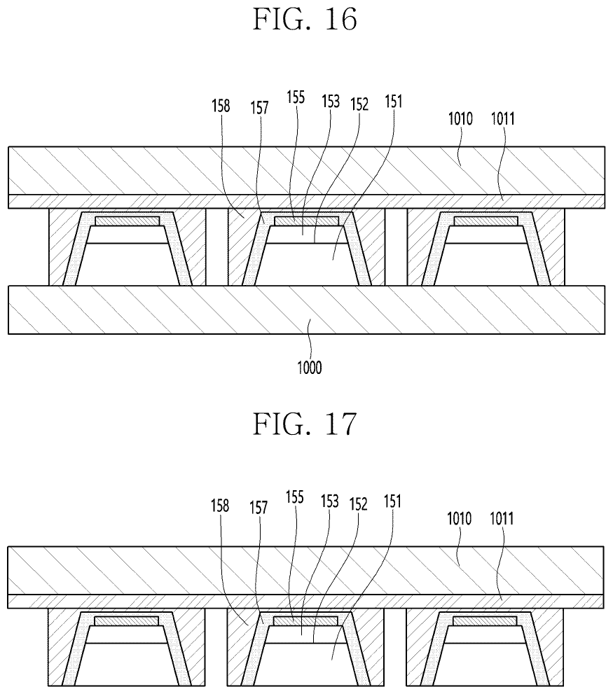

As shown in FIG. 17, the LLD process is performed so that the laser beam is intensively irradiated between the interface between the first substrate 1000 and the light-emitting portion 151, 152, and 153, so that the first substrate 1000 can be removed. In this case, one side of the light-emitting portion 151, 152 and 153, for example, the first conductivity-type semiconductor layer 151, the passivation layer 157 and the structure, may be exposed to the outside.

Even if the first substrate 1000 is removed, the plurality of light-emitting portions 151, 152 and 153 may still be bonded to the second substrate 1010 via the adhesive layer.

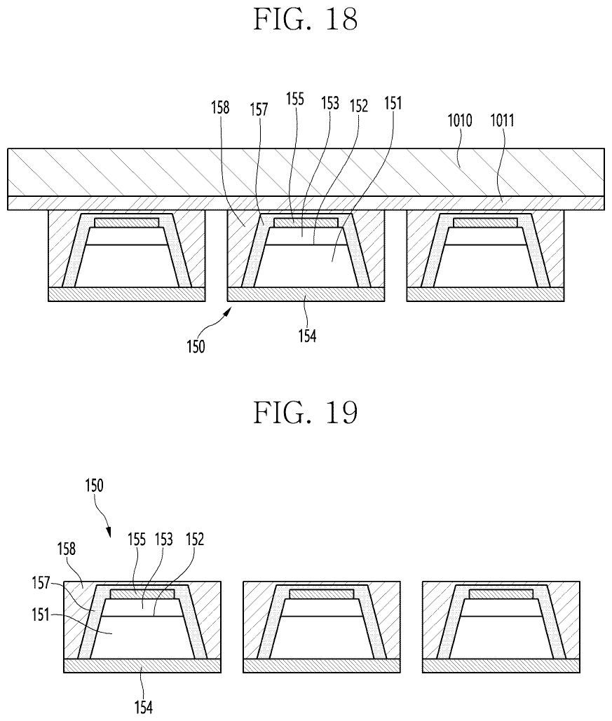

As illustrated in FIG. 18, the first electrode 154 may be formed under the light-emitting portion 151, 152 and 153, the passivation layer 157 and the structure. The first electrode 154 may comprise a plurality of layers, for example, a magnetic layer, a reflective layer, an adhesive layer, a barrier layer, etc.

The first electrode 154 may be formed and patterned on the entire area of the second substrate 1010, so that the first electrode 154 may be formed under the light-emitting portion 151, 152, and 153 and the structure. The diameter D1 of the first electrode 154 may be the same as the outer diameter of the structure, but is not limited thereto.

As illustrated in FIG. 19, the second substrate 1010 may be separated, so that a plurality of semiconductor light-emitting elements 150 may be manufactured.

The second substrate 1010 may be separated by performing wet etching using an etchant to remove the sacrificial layer 1011. After the plurality of semiconductor light-emitting elements 150 included in the wet etchant are recovered, a cleaning process and a drying process may be performed.

According to an embodiment, the structure can be used to pattern the passivation layer 157. That is, by performing a patterning process using the structure as a mask, the passivation layer 157 corresponding to the structure can be formed. Accordingly, a separate mask may be not required to pattern the passivation layer 157, so that the manufacturing cost can be reduced.

According to an embodiment, a structure may be formed along the perimeter of the passivation layer 157, thereby expanding the width L21 of the semiconductor light-emitting element 150. Accordingly, when the AR of the semiconductor light-emitting element 150 is reduced and the semiconductor light-emitting element 150 moves for self-assembly within the fluid, the semiconductor light-emitting element 150 may be moved to a normal position that is aligned with the vertical axis of the substrate 310 without being tilted, so that it is correctly assembled into the assembly hole 340H of the substrate 310, thereby preventing assembly failure and improving the assembly rate (FIG. 12).

According to an embodiment, the first electrode 154 may be formed not only under the light-emitting portion 151, 152, and 153 but also under the structure, so that the area of the magnetic layer included in the first electrode 154 may increase. Accordingly, since the magnetization of the magnetic layer is increased, the semiconductor light-emitting element 150 may move more quickly and rapidly along the magnet (500 in FIG. 12) during self-assembly, so that the assembly speed can be significantly increased.

FIG. 20 is a cross-sectional view illustrating a semiconductor light-emitting element according to a second embodiment.

Referring to FIG. 20, the semiconductor light-emitting element 150A according to the second embodiment may comprise the first electrode 154, light-emitting portion 151, 152, and 153, a passivation layer 157, a structure 158, and a second electrode 155. The semiconductor light-emitting element 150A according to the second embodiment may comprise more components than these.

The first electrode 154 may be disposed in some areas of a side portion of the structure.

In the second embodiment, the structure may have rounded surfaces 158a and 158b. For example, the structure may have an edge of a lower portion having a first round surface 158a and an edge of an upper portion having a second round surface 158b. The curvature of the first round surface 158a and the curvature of the second round surface 158b may be different. For example, the curvature of the first round surface 158a may be greater than the curvature of the second round surface 158b. Although not shown, the curvature of the first round surface 158a may be equal to or less than the curvature of the second round surface 158b.

In the second embodiment, the first electrode 154 may have a rounded shape at an edge region. The first electrode 154 may be disposed under the light-emitting portion 151, 152, and 153, the passivation layer 157, and the structure. Since the first electrode 154 is disposed on the first round surface 158a of the structure, the edge of the first electrode 154 corresponding to the first round surface 158a of the structure may also have a round shape. When the thickness is constant in the entire area of the first electrode 154, each of the lower and upper surfaces at the edge of the first electrode 154 may have a round shape.

The first electrode 154 may be disposed on a larger area on the side portion of the structure than that illustrated in FIG. 20.

According to an embodiment, since the first electrode 154 is disposed on the round surface of an edge of a lower portion of the structure, the area of the magnetic layer included in the first electrode 154 may be further increased, so that the assembly speed can be significantly increased, and thus the productivity can be improved.

FIG. 21 is a cross-sectional view illustrating a semiconductor light-emitting element according to a third embodiment.

Referring to FIG. 21, a semiconductor light-emitting element 150B according to a third embodiment may comprise a first electrode 154, light-emitting portion 151, 152, and 153, a passivation layer 157, a structure 158, and a second electrode 155. A semiconductor light-emitting element 150B according to a third embodiment may comprise more components than these.

In the structure of the third embodiment, the outer diameter of the lower side may be greater than the outer diameter of the upper side.

As the light-emitting portion 151, 152 and 153 move from the lower side to the upper side, the diameter of the light-emitting portion 151, 152 and 153 may become larger. Since the passivation layer 157 is disposed along the perimeter of the light-emitting portion 151, 152, and 153, the outer diameter of the passivation layer 157 is also larger at the lower side than at the upper side. The structure may be disposed along the perimeter of the passivation layer 157. For example, when the width of the structure disposed along the perimeter of the passivation layer 157 is the same or similar from the lower side to the upper side, the outer diameter of the structure may be larger at the lower side than at the upper side. The width of the structure may be the distance between the inner side surface in contact with the passivation layer 157 and the outer side surface on the opposite side.

According to the embodiment, since the light generated in the light-emitting portion 151, 152, and 153 and incident through the passivation layer 157 is refracted in various directions and emitted forward by the structure having the outer diameter of the lower side greater than that of the upper side, uniform light output can be possible and light efficiency can be improved.

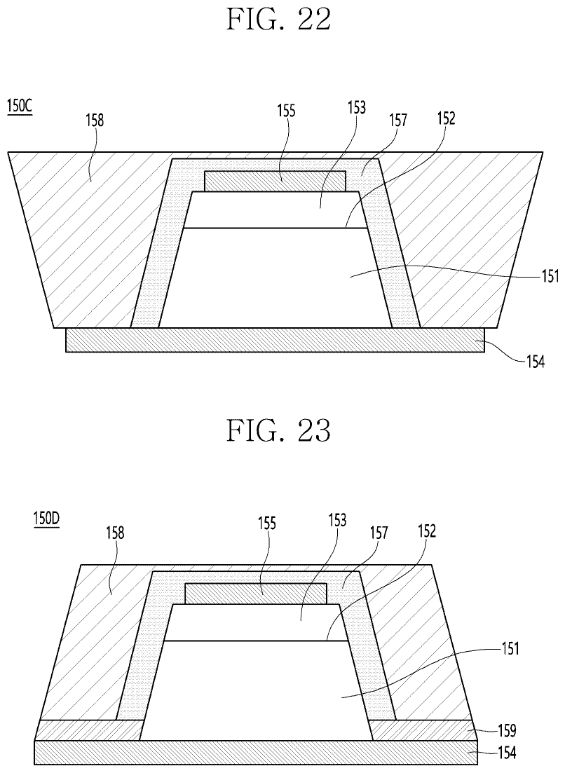

FIG. 22 is a cross-sectional view illustrating a semiconductor light-emitting element according to the fourth embodiment.

Referring to FIG. 22, the semiconductor light-emitting element 150C according to the fourth embodiment may comprise a first electrode 154, light-emitting portion 151, 152, and 153, a passivation layer 157, a structure 158, and a second electrode 155. The semiconductor light-emitting element 150C according to the fourth embodiment may comprise more components than these.

In the structure of the fourth embodiment, the outer diameter of the lower side may be smaller than the outer diameter of the upper side.

As the light-emitting portion 151, 152 and 153 move from the lower side to the upper side, the diameter of the light-emitting portion 151, 152 and 153 may become larger. Since the passivation layer 157 is disposed along the perimeter of the light-emitting portion 151, 152, and 153, the outer diameter of the passivation layer 157 is also larger at the lower side than at the upper side. The structure may be disposed along the perimeter of the passivation layer 157. For example, when the width of the structure disposed along the perimeter of the passivation layer 157 increases from the lower side to the upper side, the outer diameter of the structure may be smaller at the lower side than at the upper side. The width of the structure may be the distance between the inner side surface in contact with the passivation layer 157 and the outer side surface on the opposite side.

According to an embodiment, since the light generated at the light-emitting portion 151, 152, and 153 and incident through the passivation layer 157 is refracted in various directions and emitted forward by the structure having a lower outer diameter smaller than the upper outer diameter, uniform light output is possible and light efficiency can be improved.

Referring to FIGS. 23 to 25, a semiconductor light-emitting element with a second structure added will be described.

FIG. 23 is a cross-sectional view illustrating a semiconductor light-emitting element according to the fifth embodiment.

Referring to FIG. 23, a semiconductor light-emitting element 150D according to the fifth embodiment may comprise a first electrode 154, light-emitting portion 151, 152, and 153, a passivation layer 157, a first structure 158, a second structure 159, and a second electrode 155. The semiconductor light-emitting element 150D according to the fifth embodiment may comprise more components than these.

In the structure of the fifth embodiment, the outer diameter of the lower side may be greater than the outer diameter of the upper side.

As the light-emitting portion 151, 152 and 153 move from the lower side to the upper side, the diameter of the light-emitting portion 151, 152 and 153 may become larger. Since the passivation layer 157 is disposed along the perimeter of the light-emitting portion 151, 152, and 153, the outer diameter of the passivation layer 157 may be also larger at the lower side than at the upper side. The structure may be disposed along the perimeter of the passivation layer 157. For example, when the widths of the structures disposed along the perimeter of the passivation layer 157 are the same or similar from the lower side to the upper side, the outer diameter of the structures may be larger at the lower side than at the upper side. The width of the structure may be the distance between the inner side surface in contact with the passivation layer 157 and the outer side surface on the opposite side.

According to an embodiment, since light generated from the light-emitting portion 151, 152, and 153 and incident through the passivation layer 157 is refracted in various directions and emitted forward by a structure having a lower outer diameter greater than an upper outer diameter, uniform light output can be possible and light efficiency can be improved.

Meanwhile, the second structure 159 may be disposed along the perimeter of the passivation layer 157. The second structure 159 may be disposed on the first electrode 154. For example, the second structure 159 may be disposed between the first electrode 154 and the first structure 158. The second structure 159 may have a ring shape. The second structure 159 may have a shape corresponding to the shape of the first structure 158. The second structure 159 may be vertically stacked with the first structure 158.

For example, after partially removing the surface of the structure exposed to the outside in FIG. 17, a second structure 159 may be formed in the space where the structure is removed, and a first electrode 154 may be formed on the light-emitting portion 151, 152, and 153, the passivation layer 157, and the second structure 159, thereby manufacturing a semiconductor light-emitting element 150D according to the fifth embodiment.

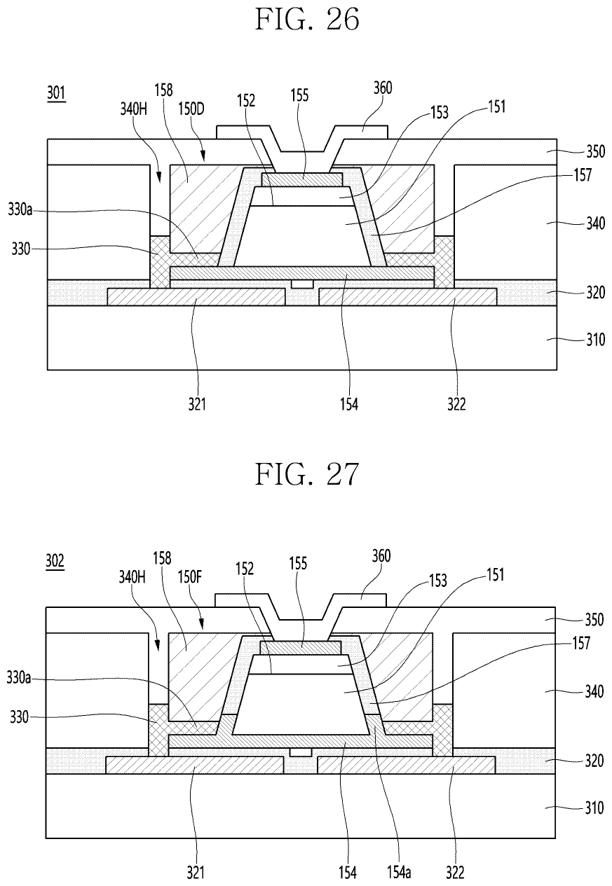

The second structure 159 may comprise a photosensitive member. After the semiconductor light-emitting element 150D is assembled on the substrate 310 during self-assembly, the second structure 159 may be removed using an exposure process. Alternatively, the second structure 159 of the semiconductor light-emitting element 150D may be removed using an exposure process before self-assembly. A metal film may be filled in the space where the second structure 159 is removed, so that a connection electrode 330 may be formed, which will be described later with reference to FIG. 26.

According to the embodiment, since the second structure 159 is provided, the second structure 159 may be simply removed using an exposure process, and then the connection electrode 330 may be formed, thereby facilitating electrical connection to the side portion of the semiconductor light-emitting element 150D.

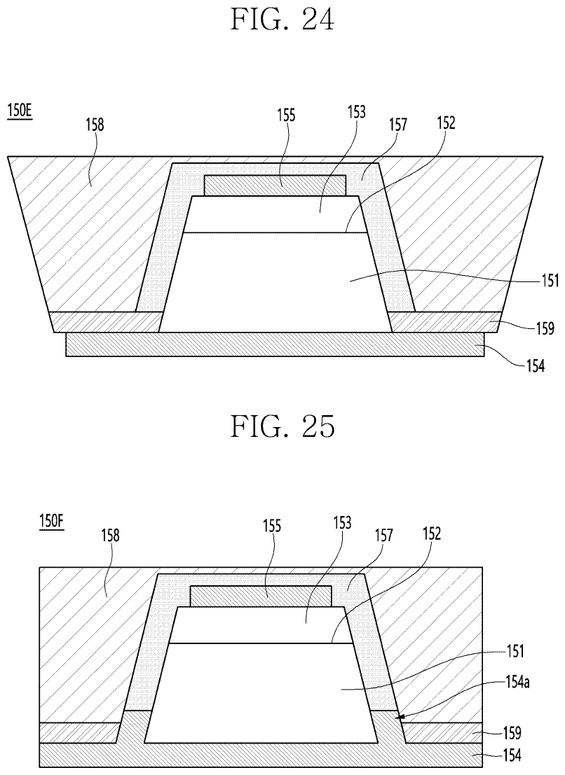

FIG. 24 is a cross-sectional view illustrating a semiconductor light-emitting element according to the sixth embodiment.

Referring to FIG. 26, the semiconductor light-emitting element 150E according to the sixth embodiment may comprise a first electrode 154, light-emitting portion 151, 152, and 153, a passivation layer 157, a first structure 158, a second structure 159, and a second electrode 155. The semiconductor light-emitting element 150E according to the sixth embodiment may comprise more components than these.

In the sixth embodiment, the structure of the first structure 158 is the same as that of the fourth embodiment (FIG. 22), and the structure of the second structure 159 is the same as that of the fifth embodiment (FIG. 23). Therefore, the sixth embodiment can be realized by a combination of the fourth embodiment (FIG. 22) and the fifth embodiment (FIG. 23).

The sixth embodiment can be easily understood from the description of the fourth embodiment (FIG. 22) and the fifth embodiment (FIG. 23), so that a detailed description thereof is omitted.

FIG. 25 is a cross-sectional view illustrating a semiconductor light-emitting element according to the seventh embodiment.

Referring to FIG. 25, the semiconductor light-emitting element 150F according to the seventh embodiment may comprise a first electrode 154, light-emitting portion 151, 152, and 153, a passivation layer 157, a first structure 158, a second structure 159, and a second electrode 155. The semiconductor light-emitting element 150F according to the seventh embodiment may comprise more components than these.

In the seventh embodiment, the first electrode 154 may comprise an extension electrode 154a that extends to the side portion of the passivation layer 157.

For example, in FIG. 17, after partially removing the surface of the structure exposed to the outside, a second structure 159 may be formed in the space from which the structure is removed. Thereafter, after partially removing the passivation layer exposed to the outside, the first electrode 154 may be formed. Accordingly, the first electrode 154 may be formed on the light-emitting portion 151, 152, and 153 and the second structure 159. In addition, as a portion of the first electrode 154, an extension electrode 154a may be formed in the space from which the passivation layer 157 is removed. Through a series of processes such as this, a semiconductor light-emitting element 150F according to the seventh embodiment may be manufactured.

According to the embodiment, the extension electrode 154a of the first electrode 154 may be also disposed on the side portion of the passivation layer 157, so that the contact area between the first conductivity-type semiconductor layer 151 and the first electrode 154 may be further increased, thereby minimizing the ohmic resistance and improving the light efficiency through smooth current flow.

### Second Embodiment

FIG. 26 is a cross-sectional view illustrating a display device according to the second embodiment.

The display device 301 according to the second embodiment may be equipped with the semiconductor light-emitting element 150D illustrated in FIG. 23. In the second embodiment, components having the same shape, structure, and/or function as those of the first embodiment (FIG. 10) are given the same drawing reference numerals and detailed descriptions are omitted.

Referring to FIG. 26, the display device 301 according to the second embodiment may comprise a substrate 310, a first assembling wiring 321, a second assembling wiring 322, a partition wall 340, a semiconductor light-emitting element 150D, and a connection electrode 330. The display device 301 according to the second embodiment may comprise more components than these.

The connection electrode 330 may be disposed around the semiconductor light-emitting element 150D within the assembly hole 340H. For example, the connection electrode 330 may be connected to a side surface of the first conductivity-type semiconductor layer 151 of the semiconductor light-emitting element 150D along the side surface of the semiconductor light-emitting element 150D.

The semiconductor light-emitting element 150D of the embodiment may be the semiconductor light-emitting element illustrated in FIG. 23.

The second structure 159 of the semiconductor light-emitting element 150D illustrated in FIG. 23 may be removed using an exposure process, so that a space exposed to the first conductivity-type semiconductor layer 151 of the semiconductor light-emitting element 150D can be formed. As described above, the second structure 159 of the semiconductor light-emitting element 150D may be performed before or after self-assembly.

As the metal film is deposited on the substrate 310, a portion of the metal film is formed around the semiconductor light-emitting element 150D within the assembly hole 340H, and may also be formed in the space where the second structure 159 is removed. Thereafter, the metal film may be patterned, so that the metal film deposited along the perimeter of the semiconductor light-emitting element 150D within the assembly hole 340H becomes the connection electrode 330. At this time, the connection electrode 330 disposed in the space where the second structure 159 was removed becomes an extended connection electrode 330a. Accordingly, the extended connection electrode 330a may be extended from one side of the connection electrode 330 and connected to the side surface of the first conductivity-type semiconductor layer 151 of the semiconductor light-emitting element 150D.

The connection electrode 330 may be disposed between the first electrode 154 and the structure. Specifically, the extended connection electrode 330a may be disposed between the first electrode 154 and the structure and connected to the side surface of the first conductivity-type semiconductor layer 151.

Meanwhile, before the connection electrode 330 is formed, the first insulating layer 320 positioned around the semiconductor light-emitting element 150D within the assembly hole 340H may be removed, so that the first assembling wiring 321 and/or the second assembling wiring 322 may be exposed. Thereafter, the connection electrode 330 may be disposed around the semiconductor light-emitting element 150D within the assembly hole 340H, so that one side of the connection electrode 330 can be connected to the first assembling wiring 321 and/or the second assembling wiring 322.

The connection electrode 330 can connect the first electrode 154 of the semiconductor light-emitting element 150D and the first assembling wiring 321 and/or the second assembling wiring 322.

According to the embodiment, the connection electrode 330 can be connected to the first electrode 154, and the first electrode 154 can be connected to the lower surface of the first conductivity-type semiconductor layer 151. In addition, the connection electrode 330 can be connected to the first conductivity-type semiconductor layer 151 via the extended connection electrode 330a. Accordingly, the first conductivity-type semiconductor layer 151 can be connected to the connection electrode 330 as well as the first electrode 154, so that current can flow more smoothly and the light efficiency can be improved.

According to the embodiment, the connection electrode 330 can be disposed between the first electrode 154 and the structure through the extended connection electrode 330a and can be connected to the side surface of the first conductivity-type semiconductor layer 151, so that the semiconductor light-emitting element 150D can be firmly fixed by the connection electrode 330, thereby enhancing the fixation.

### Third Embodiment

FIG. 27 is a cross-sectional view illustrating a display device according to the third embodiment.

The display device 302 according to the third embodiment can be equipped with the semiconductor light-emitting element 150F illustrated in FIG. 25. In the third embodiment, components having the same shape, structure, and/or function as those of the first embodiment (FIG. 10) are given the same drawing reference numerals and detailed descriptions are omitted.

Referring to FIG. 27, the display device 302 according to the third embodiment may comprise a substrate 310, a first assembling wiring 321, a second assembling wiring 322, a partition wall 340, a semiconductor light-emitting element 150F, and a connection electrode 330. The display device 302 according to the third embodiment may comprise more components than these.

The connection electrode 330 may be disposed around the semiconductor light-emitting element 150F within the assembly hole 340H. For example, the connection electrode 330 may be connected to a side surface of the first conductivity-type semiconductor layer 151 of the semiconductor light-emitting element 150F along the side surface of the semiconductor light-emitting element 150F.

The semiconductor light-emitting element 150F of the embodiment may be the semiconductor light-emitting element illustrated in FIG. 25.

The second structure 159 of the semiconductor light-emitting element 150F illustrated in FIG. 25 may be removed using an exposure process, so that a space exposed to the first conductivity-type semiconductor layer 151 of the semiconductor light-emitting element 150F can be formed. As described above, the second structure 159 of the semiconductor light-emitting element 150F may be performed before or after self-assembly.

The metal film may be deposited on the substrate 310, so that a portion of the metal film may be formed around the semiconductor light-emitting element 150F within the assembly hole 340H and may also be formed in the space where the second structure 159 is removed. Thereafter, the metal film may be patterned, so that the metal film deposited along the perimeter of the semiconductor light-emitting element 150F within the assembly hole 340H becomes the connection electrode 330. At this time, the connection electrode 330 disposed in the space where the second structure 159 was removed becomes an extended connection electrode 330a. Accordingly, the extended connection electrode 330a may be connected to the connection electrode 154a disposed on the side portion of the light-emitting portion 151, 152, and 153 by extending from one side of the connection electrode 330. The connection electrode 154a may be a region extended from the first electrode 154 disposed on the lower side of the first conductivity-type semiconductor layer 151. The connection electrode 154a may be disposed along the perimeter of the first conductivity-type semiconductor layer 151.

The connection electrode 330 may be disposed between the first electrode 154 and the structure. Specifically, the extension connection electrode 330a may be connected to the connection electrode 154a, which is disposed between the first electrode 154 and the structure and may be disposed on the side portion of the light-emitting portion 151, 152, and 153.

Meanwhile, before the connection electrode 330 is formed, the first insulating layer 320 positioned around the semiconductor light-emitting element 150F within the assembly hole 340H may be removed, so that the first assembling wiring 321 and/or the second assembling wiring 322 can be exposed. Thereafter, the connection electrode 330 may be disposed around the semiconductor light-emitting element 150F within the assembly hole 340H, so that one side of the connection electrode 330 may be connected to the first assembling wiring 321 and/or the second assembling wiring 322.

The connection electrode 330 can connect the first electrode 154 of the semiconductor light-emitting element 150F with the first assembling wiring 321 and/or the second assembling wiring 322. In addition, the connection electrode 330 can connect the extension electrode 154a, which extends from the first electrode 154 to the side portion of the first conductivity-type semiconductor layer 151, to the first assembling wiring 321 and/or the second assembling wiring 322.

According to an embodiment, the first electrode 154 may be disposed not only on the lower surface of the first conductivity-type semiconductor layer 151 but also on the side surface of the first conductivity-type semiconductor layer 151 through the extension electrode 154a, so that the current can flow more smoothly and the light efficiency can be improved. That is, the current can flow to the first electrode 154 not only through the lower surface of the first conductivity-type semiconductor layer 151 but also through the side surface of the first conductivity-type semiconductor layer 151.

According to an embodiment, the connection electrode 330 may be disposed between the first electrode 154 and the structure through the extended connection electrode 330a and may be connected to the side surface of the first conductivity-type semiconductor layer 151, so that the semiconductor light-emitting element 150F can be firmly fixed by the connection electrode 330, thereby enhancing fixation.

Meanwhile, the display device described above may be a display panel. That is, in the embodiment, the display device and the display panel may be understood to have the same meaning. In the embodiment, the display device in a practical meaning may comprise a display panel and a controller (or processor) that can control the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The embodiment can be adopted in the display field for displaying images or information. The embodiment can be adopted in the display field for displaying images or information using a semiconductor light-emitting element. The semiconductor light-emitting element can be a micro-level semiconductor light-emitting element or a nano-level semiconductor light-emitting element.

For example, the embodiment may be adopted in a TV, a signage, a smart phone, a mobile phone, a mobile terminal, a HUD for an automobile, a backlight unit for a notebook, and a display device for VR or AR.

What is claimed is:

1. A semiconductor light-emitting element semiconductor light-emitting element, comprising:
a light-emitting portion;
a first electrode under the light-emitting portion;
a second electrode on the light-emitting portion;
a passivation layer configured to surround the light-emitting portion; and
a first structure configured to surround the passivation layer.

2. The semiconductor light-emitting element of claim 1, wherein the first electrode is disposed under the light-emitting portion, the passivation layer and the first structure.

3. The semiconductor light-emitting element of claim 2, wherein a diameter of the first electrode is at least 1.5 to 3 times a diameter of the second electrode.

4. The semiconductor light-emitting element of claim 1, wherein the first electrode comprises:
a first region vertically overlapping the light-emitting portion;
a second region vertically overlapping the passivation layer; and
a third region vertically overlapping the first structure.

5. The semiconductor light-emitting element of claim 4, wherein the first region has a circular or oval shape, and
wherein the second region and the third region have ring shapes.

6. The semiconductor light-emitting element of claim 4, wherein a second structure is included on the first electrode.

7. The semiconductor light-emitting element of claim 6, wherein the second structure is disposed between the first electrode and the first structure.

8. The semiconductor light-emitting element of claim 6, wherein the second structure and the first structure surround the passivation layer.

9. The semiconductor light-emitting element of claim 6, wherein the first structure and the second structure are laminated on the third region of the first electrode.

10. The semiconductor light-emitting element of claim 6, wherein the second structure has a shape corresponding to the third region of the first electrode.

11. The semiconductor light-emitting element of claim 6, wherein the second structure comprises a photosensitive member.

12. The semiconductor light-emitting element of claim 1, wherein the first electrode comprises at least a magnetic layer, and
wherein a diameter of the magnetic layer is greater than a diameter of the light-emitting portion.

13. The semiconductor light-emitting element of claim 1, wherein the first electrode is disposed in some areas of a side portion of the first structure.

14. The semiconductor light-emitting element of claim 1, wherein the first electrode comprises an extension electrode disposed in some areas of a side portion of the light-emitting portion.

15. The semiconductor light-emitting element of claim 1, wherein the first structure has a lower side and an upper side having different outer diameters.

16. The semiconductor light-emitting element of claim 1, wherein the first structure comprises a transparent insulating member.

17. The semiconductor light-emitting element of claim 1, wherein the first structure comprises reflective particles or scattering particles.

18. A display device, comprising:
a substrate comprising a plurality of sub-pixels;
a plurality of first assembling wirings in the plurality of sub-pixels, respectively;
a plurality of second assembling wirings in the plurality of sub-pixels, respectively;
a partition wall having a plurality of assembly holes in the plurality of sub-pixels, respectively;
a plurality of semiconductor light-emitting elements in the plurality of assembly holes, respectively; and
a plurality of connection electrodes,
wherein each of the plurality of semiconductor light-emitting elements comprises:
a light-emitting portion;
a first electrode under the light-emitting portion;
a second electrode on the light-emitting portion;
a passivation layer configured to surround the light-emitting portion; and
a first structure configured to surround the passivation layer, and
wherein each of the connection electrodes is configured to connect the first electrode of each of the plurality of semiconductor light-emitting elements to at least one of the first assembling wiring or the second assembling wiring.

19. The display device of claim 1, wherein the connection electrode is disposed between the first electrode and the structure.
